(19) United States
(12) Patent Application Publication
(10) Pub. No.: US 2006/0128160 A1
(43) Pub. Date: Jun. 15, 2006

(54) Photoresist strip using solvent vapor

(76) Inventor: Woo Sik Yoo, Palo Alto, CA (US)

Correspondence Address: MACPHERSON KWOK CHEN & HEID LLP, 1762 TECHNOLOGY DRIVE, SUITE 226, SAN JOSE, CA, 95110, US

(21) Appl. No.: 11/009,764

(22) Filed: Dec. 10, 2004

(51) Int. Cl. H01L 21/302; H01L 21/461; H01L 21/306

(52) U.S. Cl. 438/725; 156/345.11

(57) ABSTRACT

Photoresist is removed from a wafer or substrate during various stages of processing by introducing a solvent vapor, along with heat, into the processing chamber. The solvent vapor chemically reacts with the photoresist to quickly and cleanly strip away the exposed photoresist.

### BACKGROUND

1. Field of Invention

This invention generally relates to semiconductor manufacturing methods and, more particularly, to methods for removing photoresist during the manufacturing of a semiconductor device.

2. Related Art

New processing and manufacturing techniques are continuously being developed to make further advancements in the development of semiconductor devices, especially semiconductor devices of decreased dimensions.

An important aspect of the semiconductor device fabrication process is the removal of the photoresist film. During the manufacture of a semiconductor wafer, numerous layers are deposited sequentially and/or etched to form the device. The layers are patterned to form the desired connections or features. The patterning is typically performed using photolithography, and in particular, by using photoresist and masks to form the desired pattern. In a typical process, a light-sensitive material, such as photoresist, is first deposited on a layer to be patterned, such as a dielectric or conductive layer.

Light is then selectively directed onto the photoresist film through a photomask, or reticle, to form desired photoresist patterns on the base material. The photoresist is then developed to transfer the pattern of the mask to the photoresist layer. Thus, after development, portions of the photoresist are removed to expose corresponding underlying portions of the previous layer. If the photoresist is negative, the removed portions correspond to regions of the resist not exposed by the mask. If the photoresist is positive, the removed portions correspond to regions of the resist exposed by the mask. Regardless of the polarity, once the resist is developed, additional processing, such as deposition of another layer, implantation, or etching, can be performed using the pattern defined by the photoresist.

Following the additional processing; the remaining photoresist is removed or stripped. The photoresist may also be stripped at some point in the photolithography process to allow re-work, e.g., re-coating, exposing, and developing, of the wafer due to poor processing in one of the previous photolithography steps. For example, an overlay or critical dimension measurement performed after one of the intermediate photolithography steps may identify that the photoresist pattern is not suitable for further processing. Such a condition might have been caused by a defect, miscalibration, or other such processing problem in the stepper or developer.

Typically, photoresist removal or stripping is performed using either a dry strip or a wet strip. In a dry strip, a plasma strip tool typically uses plasma-enhanced, ionized oxygen/oxygen radicals to remove the resist. In a wet strip, liquids, such as sulfuric acid/peroxide mixes followed by rinses or a sequence of standard cleans, are typically used. The wet method is generally preferable to the dry method, since it does not damage the underlying substrate. However, in wet stripping methods the chemical bath that is needed to remove the resist can also contaminate the substrate. In addition, particles that remain in the chemical bath can re-adhere to the substrate. Thus, in the wet stripping method a cleaning step, such as a rinse, is required before the substrate is ready for subsequent processing, such as annealing.

The dry stripping method typically includes exposing the substrate and the photoresist to a plasma. The plasma formation occurs at low pressure. Thus, the amount of reactive gas available to the removal process is low. For example, in an oxygen plasma that is formed at about 1 Torr, the amount of O₂ available to react with the photoresist is about 1000 times less than is available in air.

Unfortunately, substrate damage can occur as the substrate is exposed to the plasma due to the ion bombardment. In addition, dry stripping methods usually leave residue on the wafer surface even after the stripping processes are complete. As a result, the photoresist stripped wafer has to be reprocessed by wet cleaning before conducting an ion implant anneal or other process, which adds another level of complexity to the overall substrate processing.

In addition, accurate control of the stripping process is important for preventing defects in the wafer. If the photoresist strip time is too short (i.e., understripping), remnants of the photoresist layer will be present on the wafer, interfering with subsequent processing steps. If the strip time is too long (i.e., overstripping), the wafer may be damaged by unnecessary exposure to ion charging effects, and also the processing time for completing the wafer is lengthened. Typically, a minimum strip time designed to provide a certain amount of overstripping to ensure complete removal of the photoresist is programmed into the recipe of the developer. However, variations, such as in the photoresist, developer, and/or photoresist layer thickness, may result in different photoresist strip rates for various wafers in the same or different lots. Accordingly, a minimum strip time does not always ensure that all of the photoresist is removed. Increasing the strip time to encompass such process variations could result in wafer damage and lengthen processing time.

As the size of semiconductor devices continues to decrease, typical photoresist removal methods must be able to increase the rate of residual-free resist removal and decrease the amount of damage caused in the substrate layers underlying the resist film.

Therefore, there is a need for a photoresist stripping or etching method that is fast and clean and overcomes disadvantages of conventional methods discussed above.

### SUMMARY

According to one aspect of the present invention, solvent vapor is used, along with thermal energy or heat, to strip photoresist from the surface of a substrate or wafer. Using this stripping process increases the rate of resist removal, while also reducing the amount of residue and particles remaining on the substrate after the resist removal process, for a fast and clean photoresist removal process.

Typically, the wafer has been processed to the point where photoresist needs to be stripped from the surface. The wafer is placed or remains in a process chamber at a temperature between approximately room temperature and 500° C. A vapor solvent is introduced into the chamber, which acting with the heated wafer, strips photoresist from the surface of the wafer.

In one embodiment, the vapor solvent is generated by providing a solvent chamber configured to hold liquid solvent, heating the solvent to provide saturated solvent vapor at a desired pressure, and diffusing the saturated solvent vapor from the solvent chamber to a process chamber for photoresist stripping. In another embodiment, a bubbler-based delivery system is used to provide the solvent vapor to the process chamber. In this type system, a carrier gas is introduced into liquid solvent, causing bubbles to escape past the surface of the solvent. The resulting carrier gas and solvent vapor then flows through a pipe to the processing chamber. In a third embodiment, liquid solvent is held in a container. An inert gas is introduced into the container to pressurize the volume above the liquid solvent. This causes the liquid solvent to travel through a pipe to a liquid mass flow controller, which directs the liquid solvent to either a vaporizer or a heated solvent distributor in the process chamber. With a vaporizer, the liquid solvent is vaporized and solvent vapor is introduced in the process chamber. With a heated distributor, such as a heated showerhead, liquid solvent exits the heated showerhead and into the process chamber in vapor form.

The present invention provides several advantages over conventional photoresist stripping methods, including less cross-contamination from residue, no need for reprocessing in wet bench, process step reduction, benefits of all dry processing, and easy process integration.

These and other features and advantages of the present invention will be more readily apparent from the detailed description of the preferred embodiments set forth below taken in conjunction with the accompanying drawings.

### BRIEF DESCRIPTION OF THE DRAWINGS

FIG. 1 is a schematic illustration of a side view of an embodiment of a semiconductor wafer processing system that establishes a representative environment of the present invention;

FIG. 2 is a simplified cross-sectional view of a processing chamber of FIG. 1 in accordance with an embodiment of the present invention;

FIG. 3 is a simplified block diagram of a solvent vapor delivery system according to one embodiment;

FIG. 4 is a simplified block diagram of a solvent vapor delivery system according to a second embodiment;

FIG. 5 is a simplified block diagram of a solvent vapor delivery system according to a third embodiment; and

FIG. 6 is a simplified block diagram of a solvent delivery system according to a fourth embodiment.

Embodiments of the present invention and their advantages are best understood by referring to the detailed description that follows. It should be appreciated that like reference numerals are used to identify like elements illustrated in one or more of the figures.

### DETAILED DESCRIPTION

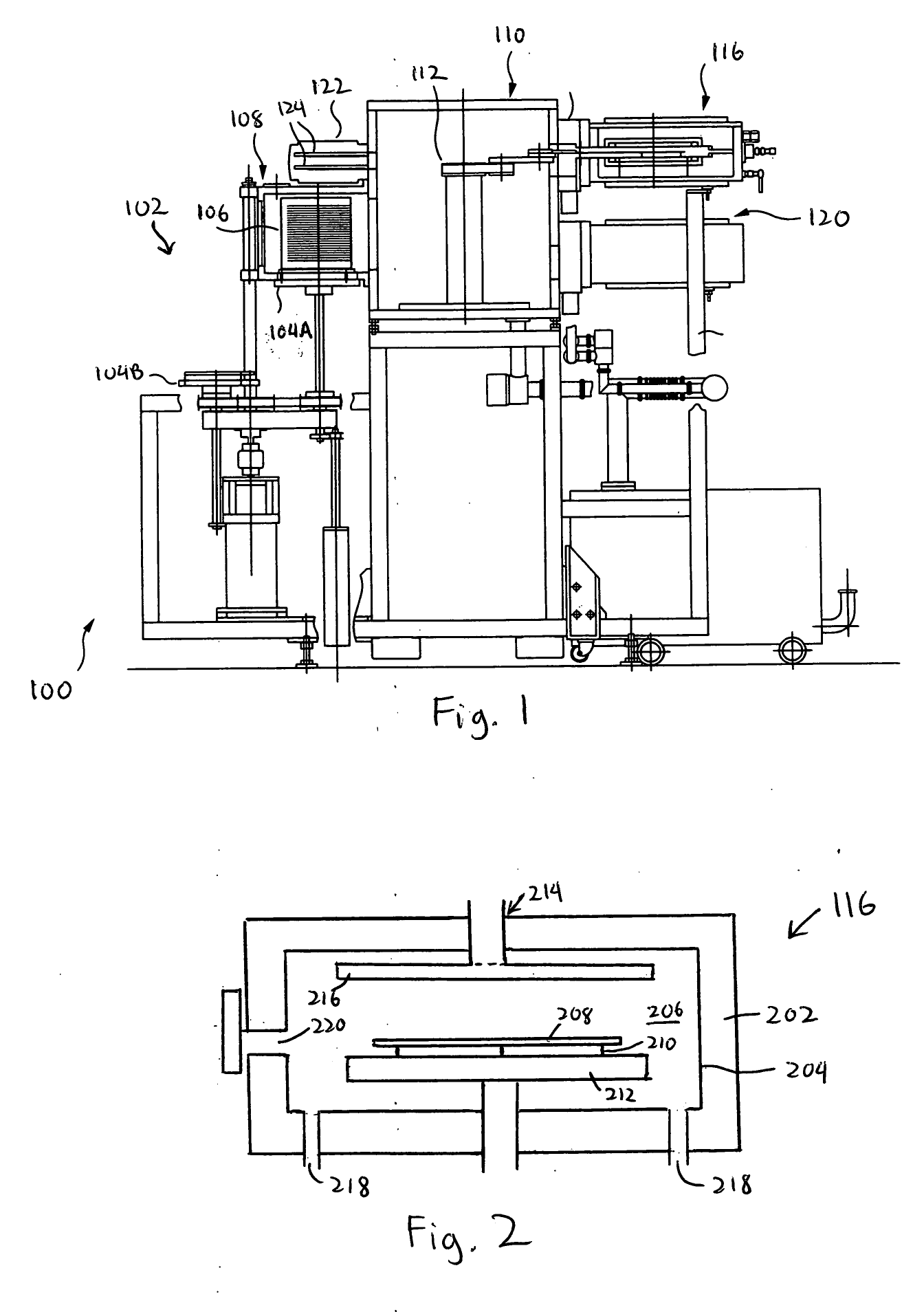

FIG. 1 is a schematic illustration of a side view of one embodiment of a semiconductor wafer processing system 100 that establishes a representative environment of the present invention. Processing system 100 includes a loading station 102 which has multiple platforms 104A and 104B for supporting and moving a wafer carrier or cassette 106 up and into a loadlock 108. Wafer cassette 106 may be a removable cassette which is loaded into platform 104A or 104B, either manually or with automated guided vehicles (AGV). Wafer cassette 106 may also be a fixed cassette, in which case wafers are loaded onto cassette 106 using conventional atmospheric robots or loaders (not shown), or a front opening unified pod (FOUP). Once wafer cassette 106 is inside loadlock 108, loadlock 108 and a transfer chamber 110 are maintained at atmospheric pressure or else are pumped down to vacuum pressure. A robot 112 within transfer chamber 110 rotates toward loadlock 108 and picks up a wafer from cassette 106. A processing chamber 116 for removing or stripping photoresist, which may be at a pressure between 0.1 Torr and 1000 Torr, accepts the wafer from robot 112 through a gate valve. Optionally, additional reactors or processing chambers may be added to the system, for example a processing chamber 120 for annealing. Robot 112 then retracts and, subsequently, the gate valve closes to begin the processing of the wafer, such as stripping photoresist, as described below. After the wafer is processed, the gate valve opens to allow robot 112 to remove and place the wafer. Optionally, a cooling station 122 is provided with platforms 124, which allows the newly processed wafers to cool before they are placed back into a wafer cassette in loadlock 108. Commonly-owned U.S. Pat. No. 6,410,455 discloses a representative wafer processing system and is incorporated by reference in its entirety.

FIG. 2 is a simplified cross-sectional view of processing chamber 116 for stripping photoresist in accordance with an embodiment of the present invention. Externally, thermal processing chamber 116 may be a metallic shell 202 preferably made of aluminum or similar metal, defining an opening configured to receive a wafer for processing.

Thermal processing chamber 116 includes a process tube 204, which defines an interior cavity 206 in which processing of a wafer 208 can occur. In one embodiment, process tube 204 may be constructed with a substantially rectangular cross-section, having a minimal internal volume surrounding wafer 208. Process tube 204 can be made of quartz, but may be made of silicon carbide, Al₂O₃, or other suitable material. Process tube 204 can be capable of being pressurized with pressures between about 0.001 Torr to 1000 Torr, for example, between about 0.1 Torr and about 760 Torr.

Positioned within cavity 206 of process tube 204 are wafer support standoffs 210, which support the single wafer 208. Standoffs 210 may be any high temperature resistant material, such as quartz. In some embodiments, standoffs 210 may have a height of between about 50 μm and about 20 mm. Standoffs 210 support and separate wafer 208 from a susceptor or heater 212, which is used to heat wafer 208 to a desired processing temperature. Chamber heating elements (not shown) may be located adjacent the process tube to heat the chamber to a desired temperature, for example, from room temperature up to 500° or more. Heat diffusing members can be positioned between the heating elements and process tube 204. The heat diffusing members absorb the thermal energy output from the heating elements and dissipate the heat evenly across process tube 204. The heat diffusing members may be any suitable heat diffusing material that has a sufficiently high thermal conductivity, preferably silicon carbide, Al₂O₃, or graphite.

Located above wafer 208 is an inlet port 214 for introducing solvent into cavity 206 and onto wafer 208 for stripping photoresist from wafer 208. Note that gas inlet or inlets may be located in any suitable location. One or more showerheads 216 coupled to gas inlet port 214 may be located above wafer 208 to disperse the solvent over and across wafer 208 positioned on standoffs 210. Conventional showerheads may be used, such as one or more showerheads, each with numerous holes that inject a uniform flow of gas or vapor onto the wafer surface. The showerheads may be any suitable shape, such as triangular, with single or multiple zones to provide desired (e.g., equal) exposure to all areas of wafer 208. Any suitable gas or vapor distribution system can be used, which can fill cavity 206 with solvent vapor. Chamber 116 also has one or more exhaust ports 218, located at the bottom of tube 204, for expelling gases or vapor.

An opening 220 provides access for the loading and unloading of wafer 208 before and after processing. Opening 220 may be a relatively small opening. In one embodiment, opening 220 may have a height and width large enough to accommodate a wafer of between about 0.5 to 2 mm thick and up to about 300 mm (˜12 in.) in diameter, and a portion of robot 106 (FIG. 1) passing therethrough. The height of opening 220 can be between about 18 mm and 50 mm, for example, no greater than about 20 mm. It should be understood that the size of process tube 204 and opening 220 can be made any size large enough to accommodate the processing of any sized wafer.

In one embodiment, wafer 208 having a layer of exposed photoresist is placed into process chamber 116 through opening 220. For example, processing before placement into the chamber can comprise conventional steps, such as the following. Wafer 208 is first exposed to a light source using a photomask to pattern the wafer. Wafer 208 is then transferred to an oven, where a post exposure bake is conducted. Following the post exposure bake, wafer 208 is transferred to a cool down station, and then to a developer, where the unexposed photoresist is removed. A subsequent processing tool performs additional processing of wafer 208 using the pattern formed in the photoresist, such as deposition of an additional layer, ion implantation, wet or dry etching, etc. Following the subsequent processing in the subsequent processing tool, wafer 208 is transferred to process chamber 116, where remnants of the patterned photoresist layer are removed.

Chamber 116 is brought to a temperature of approximately 20° C. to 600° C. and a pressure of approximately 0.1 Torr to 1000 Torr. Solvent vapor is then delivered into chamber 116, which when combined with heat, quickly and efficiently strips the exposed portions of photoresist, with typical times between 1 second and approximately 10 minutes. The type of solvent used depends on various factors, such as the type photoresist and the characteristics of the photoresist, such as whether the photoresist is positive or negative, the wafer surface underneath the photoresist, the condition of the photoresist, and production considerations. As used herein, solvent refers to any solution that chemically reacts with the photoresist to remove or strip away the photoresist. Suitable solvents include, but are not limited to, sulfuric acid plus an oxidant (e.g., hydrogen peroxide, ammonium persulfate, nitric acid), acetone, sulfonic acid (an organic acid) combined with chlorinated hydrocarbon solvents such as duodexabenzene, mixtures of chromium trioxide in sulfuric acid, N-methyl pyrrolidine (NMP)/Alkanolamine, dimethylsulfoxide (DMSO)/Monothanolamine, dimethylacetamide (DMAC)/Diethanolamine, sulfolane, dimethylforamide (DMF), and Hydroxylamine (HDA). The solvents may be introduced in various ways, such as vapor from a temperature controlled liquid, vaporized solvent from a vaporizer, or liquid injection into a heated chamber. Details will be provided below.

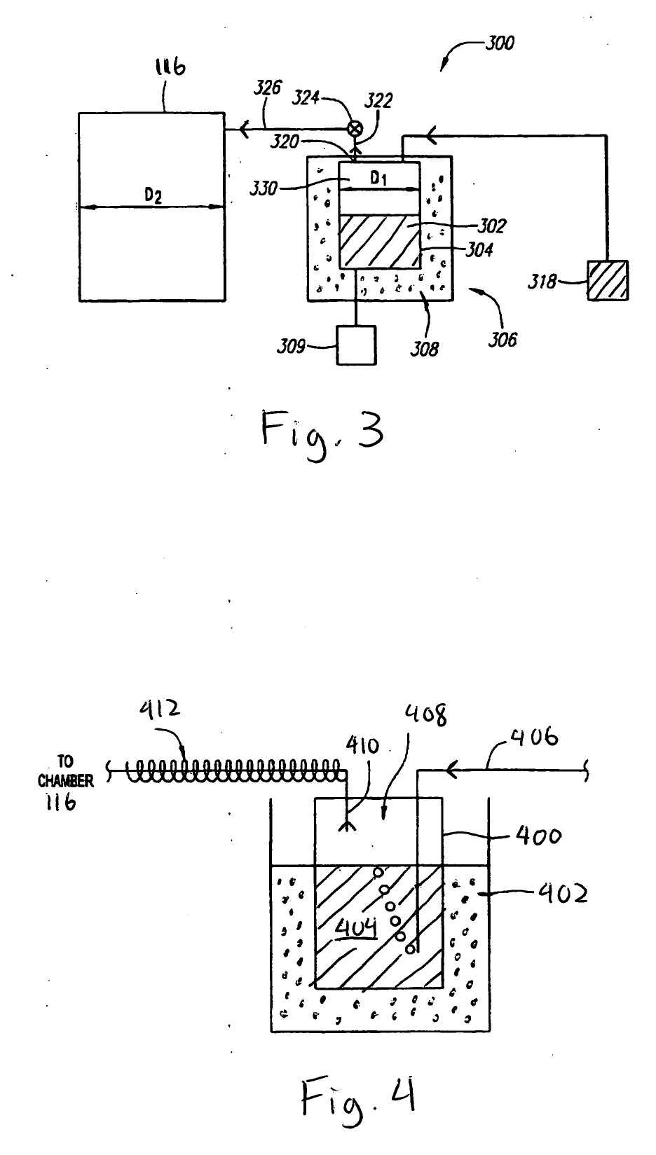

FIG. 3 illustrates one type of solvent vapor delivery system 300 in accordance with an embodiment of the present invention. A solvent liquid 302 is enclosed in a solvent chamber 304, which is in thermal contact with a heat source 309 to heat solvent liquid 302. Heat source 309 can be any heating apparatus which uniformly heats and controls the temperature of solvent liquid 302, such as a heating bath, heating plate, or convection oven. In the embodiment illustrated in FIG. 3, a temperature-controlled liquid bath 308 is used to heat solvent chamber 304. Chamber 304 is at least partially submerged in liquid bath 308 to a level, where solvent liquid 302 is at least fully submerged in the bath fluid. In an alternative embodiment, solvent chamber 304 is fully submerged in the liquid bath to allow solvent vapor as well as the precursor liquid to be heated. In this illustrative embodiment, the liquid bath is heated to between approximately 0° C. and approximately 100° C.

Bath fluids having low volatility, high boiling points, and/or high heat capacities which can be used in liquid bath 308 are available commercially. Examples of bath fluids, with no intention to limit the invention thereby, are the Silicone series of bath fluids, available from Cole-Parmer Instrument Co., Vernon Hills, Ill.

Solvent chamber 304 includes a control diameter D1. As D1 is made larger, the surface area of exposed solvent liquid 302 is increased. Accordingly, saturated solvent vapor is more quickly formed and made available for delivery to the processing chamber upon heating.

Control diameter D1 also controls for backflow or negative pressure drop during solvent vapor delivery to processing chamber 116, which includes a diameter D2. For example, as control diameter D1 is made larger relative to diameter D2, the pressure drop between solvent chamber 304 and processing chamber 116 becomes negligible, thereby controlling for backflow during solvent vapor delivery. In one embodiment, control diameter D1 is in the range of between approximately 25 mm and approximately 300 mm, and diameter D2 is in the range of between approximately 50 mm and approximately 1000 mm.

Optionally, solvent chamber 304 is operably connected to a liquid solvent source 318. Solvent source 318 may continuously feed solvent liquid to chamber 304 or it may feed discrete amounts of solvent liquid as needed. In the alternative, chamber 304 is a stand-alone batch chamber that is manually refilled with solvent liquid as needed.

The source gas delivery system further includes a vapor pathway allowing saturated solvent vapor to enter the processing chamber from the solvent chamber. In one embodiment, the vapor pathway includes a vapor inlet 320 located in a space 330 above the surface of liquid solvent 302 in chamber 304. A first end of a pipe 322 is operably connected to vapor inlet 320. A second end of pipe 322 is operably connected to an open/close valve 324. A first end of a pipe 326 is also operably connected to open/close valve 324, and a second end of pipe 326 is operably connected to processing chamber 116. Valves and seals which can be used in this system are available commercially from Rohm and Haas Company, North Andover, Mass.

Another type of delivery system for the solvent vapor is a bubbler-based system. FIG. 4 illustrates a typical bubbler-based delivery system, which includes an enclosed solvent chamber 400 at least partially submerged in the liquid of a heating bath 402. The temperature of the bath may be adjusted to heat or cool solvent chamber 400, such as with heaters located within or proximate to the chamber. In operation, solvent chamber 400 contains a liquid solvent 404. An inert carrier gas travels to precursor chamber 400 along a first pipe 406. The open end of first pipe 406 is located in solvent 404. The carrier gas exits the pipe and bubbles to the surface of the liquid solvent. Contained within precursor chamber 400 above the surface of solvent 404 is a space 408. An input end for a second pipe 410 is located in space 408 above the surface of solvent 404. As the stream of the carrier gas passes through solvent 404 and bubbles to the liquid surface, solvent vapor attains its equilibrium vapor pressure more quickly. A “sparger” (a cap with multiple small perforations) is sometimes added to the end of first pipe 406 to ensure formation of small bubbles and rapid equilibration. The carrier gas and solvent vapor enter second pipe 410 and flow to processing chamber 116 (FIG. 2), where the solvent vapor reacts in a heated environment with exposed photoresist to strip the photoresist from the wafer surface. The temperature of pipe 410 is controlled by heating elements, such as heating coils 412, surrounding pipe 410 to keep the solvent vapor from condensing during transport to processing chamber 116. The rate of solvent vapor flow into chamber 116 can be controlled by adjusting the temperature of heating bath 402 and/or the flow rate of the carrier gas.

FIG. 5 illustrates another solvent vapor delivery system using a liquid mass flow controller (LMFC) to measure and control the flow rate of liquid precursor to a vaporizer. An enclosed solvent chamber 500 includes a solvent liquid 502. An inert gas travels to solvent chamber 500 along a first pipe 504. The open end of the pipe is located above the surface of solvent liquid 502. Inert gas exits first pipe 504 and pressurizes the solvent liquid within chamber 500. An input end for a second pipe 506 is located in solvent liquid 502. When the inert gas enters chamber 500, the space above the precursor liquid becomes pressurized such that the level of the solvent liquid within chamber 500 is lowered. Solvent liquid 502 enters second pipe 506 and is transported to a LMFC 508. A valve 510 can control the amount of liquid passing to LMFC 508. The solvent liquid exits LMFC 508 and is transported to a vaporizer 512. The solvent liquid is vaporized and is then typically entrained in a carrier gas which delivers it through a heated pipe 514. The temperature of the pipe is controlled by heating elements, such as heating coils 516, surrounding the pipe. The solvent vapor is then introduced into process chamber 116.

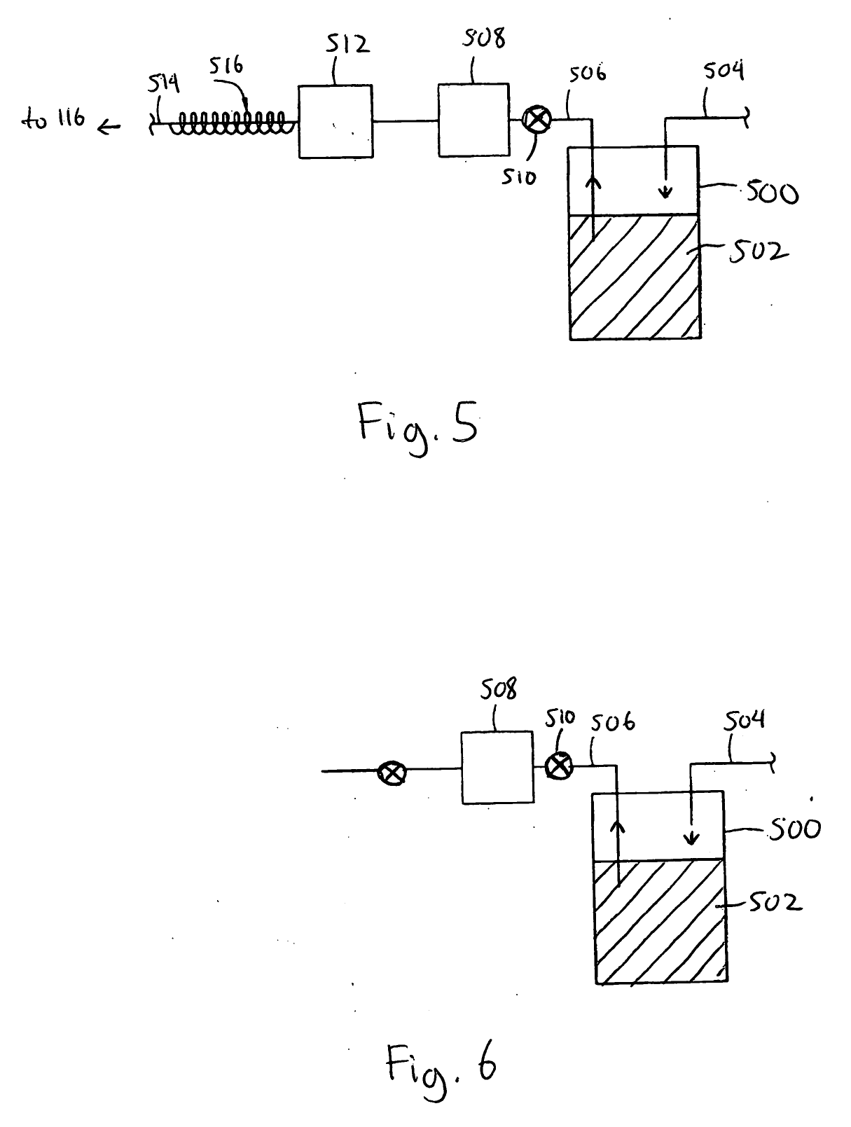

FIG. 6 shows another type of solvent delivery system, similar to that shown in FIG. 5. Enclosed solvent chamber 500, solvent liquid 502, first pipe 504, second pipe 506, LMFC 508, and valve 510 are similar to the system of FIG. 5 and thus, their description is omitted here. After the solvent liquid exits LMFC 508, it is injected through a gas or liquid heated delivery system and into process chamber 116. The gas or liquid delivery system, in one embodiment, is one or more heated showerheads, which when the liquid solvent passes through, emits a solvent vapor into process chamber 116.

Thus, once a suitable solvent is selected, the solvent is vaporized and introduced in the process chamber. The solvent vapor, along with heat in the chamber, chemically strips or removes photoresist quickly and efficiently, without disadvantages of conventional dry or wet stripping processes. For example, photoresist can be removed at a rate of about 0.001 μm/min to about 10 μm/min with less by-products than wet strips. High wafer temperature and high vapor pressure of aggressive solvents typically provide a higher removal rate. Process parameters depend, in large part, on the type of solvent or etchant. After photoresist removal, further processing can continue, such as implant annealing, either in the same chamber or in another chamber.

If in the same chamber, the chamber is brought to an annealing temperature. The processing chamber is also purged, for example, using a heated exhaust tube and venturi to remove gases before commencing with annealing.

Alternatively, referring to FIG. 1, the wafer can be removed from processing chamber 116 and placed in processing chamber 120 for annealing. The temperature in processing chamber 120 is raised to an annealing temperature between, for example 25° C. and 1300° C. to activate the implanted species. Advantageously, using two chambers to separately conduct the thermal ashing and annealing may increase the wafer throughput.

Having thus described embodiments of the present invention, persons skilled in the art will recognize that changes may be made in form and detail without departing from the scope of the invention. For example, the photoresist stripping process of the present invention can be integrated with different semiconductor manufacturing processes, such as implant annealing, using single wafer rapid thermal processing (RTP) or batch wafer processing system. Thus the invention is limited only by the following claims.

What is claimed is:

1. A photoresist removal method comprising:
providing a substrate having exposed portions of photoresist;
placing the substrate into a first processing chamber; and
introducing solvent vapor into the first processing chamber, wherein the solvent vapor chemically reacts with the photoresist to remove the exposed portions of photoresist from the substrate.

2. The method of claim 1, further comprising heating the substrate to promote removal of photoresist using solvent vapor.

3. The method of claim 2, wherein the heating comprises heating the first processing chamber.

4. The method of claim 3, wherein the temperature of the first processing chamber is between approximately 20° C. and 600° C.

5. The method of claim 1, wherein the introducing comprises filling the first processing chamber with the solvent vapor.

6. The method of claim 1, further comprising adjusting the rate of solvent vapor introduction to change the rate of photoresist removal.

7. The method of claim 1, further comprising adjusting the temperature in the first processing chamber to change the rate of photoresist removal.

8. The method of claim 1, further comprising adjusting the concentration of the solvent vapor to change the rate of photoresist removal.

9. The method of claim 1, wherein the introducing comprises:
providing a container of liquid solvent;
heating the liquid solvent to provide a saturated solvent vapor in the container; and
delivering the solvent vapor from the container to the first processing chamber.

10. The method of claim 9, wherein the delivering is through a valve.

11. The method of claim 1, wherein the introducing comprises:
providing a container of liquid solvent;
introducing a carrier gas into the liquid solvent to cause bubbles to escape from the liquid solvent; and
delivering solvent vapor from the container to the first processing chamber.

12. The method of claim 1, wherein the introducing comprises vaporizing a liquid solvent.

13. The method of claim 1, wherein the introducing comprises passing a liquid solvent through a heated delivery system.

14. The method of claim 13, wherein the heated delivery system comprises a heated showerhead.

15. The method of claim 12, wherein the introducing further comprises:
providing a container of liquid solvent;
introducing a gas in the container to force the liquid solvent out of the container; and
passing the liquid solvent through a liquid mass flow controller prior to the vaporizing.

16. The method of claim 13, wherein the introducing further comprises:
providing a container of liquid solvent;
introducing a gas in the container to force the liquid solvent out of the container; and
passing the liquid solvent through a liquid mass flow controller prior to the heated delivery system.

17. The method of claim 1, wherein pressure in the first processing chamber is between approximately 1.0 Torr and 1000 Torr.

18. The method of claim 1, further comprising transferring the substrate to a second processing chamber after photoresist removal.

19. The method of claim 18, wherein the second processing chamber is an annealing chamber.

20. A semiconductor processing system for removing photoresist on a substrate, the system comprising:
a processing chamber;
a support within the chamber for supporting the substrate;
a heating element within the chamber;
a solvent vapor delivery system to deliver solvent vapor into the chamber; and
an outlet port to exhaust the processing chamber.

21. The system of claim 20, further comprising:
a container of liquid solvent;
a gas tube to introduce gas into the liquid solvent to cause bubbles to escape from the liquid solvent;
a gas outlet to carry solvent vapor from the container to the processing chamber.

22. The system of claim 20, further comprising:
a container of liquid solvent;
a gas tube to introduce gas into the liquid solvent;
a heating element to heat the liquid solvent; and
a gas outlet to carry saturated solvent vapor from the container to the processing chamber.

23. The system of claim 20, further comprising:
a container of liquid solvent;
a gas tube to introduce gas into the container;
a tube to carry liquid solvent out of the container;
a liquid mass flow controller coupled to the tube to control flow of the liquid solvent; and
a second tube that couples the liquid mass flow controller to the solvent vapor delivery system.

24. The system of claim 23, further comprising a vaporizer coupled between the liquid mass flow controller and the solvent vapor delivery system.

25. The system of claim 23, wherein the solvent vapor delivery system heats the solvent from the liquid mass flow controller.
